(19) United States
(12) Patent Application Publication
(10) Pub. No.: US 2018/0076179 A1
(43) Pub. Date: Mar. 15, 2018

(54) STACKED TYPE CHIP PACKAGE STRUCTURE AND MANUFACTURING METHOD THEREOF

(71) Applicant: Powertech Technology Inc., Hsinchu County (TW)

(72) Inventors: Hung-Hsin Hsu, Hsinchu County (TW); Nan-Chun Lin, Hsinchu County (TW); Shang-Yu Chang Chien, Hsinchu County (TW)

(73) Assignee: Powertech Technology Inc., Hsinchu County (TW)

(21) Appl. No.: 15/640,595

(22) Filed: Jul. 3, 2017

Related U.S. Application Data
(60) Provisional application No. 62/385,261, filed on Sep. 9, 2016.

(51) Int. Cl. H01L 25/065; H01L 21/56; H01L 25/00; H01L 23/31; H01L 23/00; H01L 23/522

(52) U.S. Cl. CPC H01L 25/0657; H01L 21/56; H01L 25/50; H01L 23/3107; H01L 24/32; H01L 2924/0132; H01L 24/14; H01L 24/17; H01L 2224/32145; H01L 2924/01029; H01L 2924/01028; H01L 23/5226

(57) ABSTRACT

A stacked-type chip package structure includes a first chip, first terminals, a first redistribution layer, a first encapsulant, a second chip, second terminals, a second redistribution layer and through pillars. Each first chip includes a first active surface and first pads located on the first active surface. The first terminals are disposed on the first pads. The first redistribution layer is electrically connected to the first chip. The first encapsulant encapsulates the first chip and exposes top surfaces of the first terminals. The second chip is disposed over the first encapsulant. The second chip includes a second active surface and second pads located on the second active surface. The second terminals are disposed on the second pads. The second redistribution layer is electrically connected to the second chip. The through pillars electrically connect the first redistribution layer and the second redistribution layer.

### CROSS REFERENCE TO RELATED APPLICATION

This application claims the priority benefit of U.S. provisional application Ser. No. 62/385,261, filed on Sep. 9, 2016. The entirety of the above-mentioned patent application is hereby incorporated by reference herein and made a part of specification.

### BACKGROUND OF THE INVENTION

### Field of the Invention

The present disclosure generally relates to a chip package structure and a manufacturing method thereof. More particularly, the present disclosure relates to a stacked type chip package structure and a manufacturing method thereof.

### Description of Related Art

Currently, electronic devices commensurate with market demands and advancement of manufacturing technologies are progressing. In consideration of the portability and growing demands for computer, communication and consumer (3C) electronic products, a conventional single chip package structure gradually fails to comply with the requirements in the market. Namely, trends of lightness, thinness, shortness, smallness, compactness, high density, and low costs must be taken into account in designing the products. As such, in view of the requirements for lightness, thinness, shortness, smallness, and compactness, integrated circuits (IC) with various functions are stacked in different manners for reducing dimensions and thickness of package products, which has become a mainstream strategy in the package market. At present, the package products having a package on package (POP) structure or a package in package (PIP) structure are researched and developed in response to such trend.

In general, the via hole in the package is typically formed by laser beam. In this case, the laser beam passes through the insulating layer, and the electrode pad of the chip made of Al and the like may be flied apart by irradiation of the laser beam. As a result, the device including a semiconductor chip is disadvantageously damaged. Also, with the increasing complexity and the enhancement of the functions of the electronic devices, the required number of the chips that are stacked in the POP structure and the PIP structure is increased day by day. As such, it is imperative to control the thickness of the package and electrical contacts, so as to reduce the thickness of the chip package structure in a package process.

### SUMMARY OF THE INVENTION

Accordingly, the present disclosure is directed to a stacked type chip package structure which has favourable reliability, lower production cost and thinner overall thickness.

The present disclosure is directed to a manufacturing method of a stacked type chip package structure for manufacturing the stacked type chip package structure described above.

The present disclosure provides a manufacturing method of a stacked type chip package structure including the following steps. At least one first chip is disposed over a carrier, wherein the first chip includes a first active surface and a plurality of first pads located on the first active surface, and the first terminals are disposed on the first pads. A first redistribution layer s formed to electrically connect to the first chip. A first encapsulant is formed to encapsulate the first chip and exposes a top surface of each of the first terminals. At least one second chip is disposed over the first encapsulant, wherein the second chip includes a second active surface and a plurality of second pads located on the second active surface, and the second terminals are disposed on the second pads. A second redistribution layer is formed for being electrically connected to the second chip. A plurality of through pillars are formed, wherein the through pillars electrically connect the first redistribution layer and the second redistribution layer.

The present disclosure further provides a stacked type chip package structure including a first chip, a plurality of first terminals, a first redistribution layer, a first encapsulant, a second chip, a plurality of second terminals, a second redistribution layer, and a plurality of through pillars. Each of the first chips includes a first active surface and a plurality of first pads located on the first active surface. The first terminals are disposed on the first pads. The first redistribution layer is electrically connected to the first chip. The first encapsulant encapsulates the first chip and exposes top surfaces of the first terminals. The second chip is disposed over the first encapsulant, wherein the second chip includes a second active surface and a plurality of second pads located on the second active surface. The second terminals are disposed on the second pads. The second redistribution layer is electrically connected to the second chip. The through pillars electrically connect the first redistribution layer and the second redistribution layer.

In light of the foregoing, in the present disclosure, the first terminals are formed on the first chip and then the first chip is disposed on the carrier. The first encapsulant is then formed to encapsulate the first chip, and the first redistribution layer is formed on the first encapsulant to electrically connect the first chip. Then, the second chip with second terminals formed thereon may be sequentially stacked over the first encapsulant and the second redistribution layer is formed to be electrically connected to the second chip, and the through pillars is formed to electrically connect the first and second redistribution layers. With such configuration, the thickness of the stacked type chip package structure is further reduced. Also, the process of forming conductive vias for the chips by laser drilling is omitted, so as to reduce the production cost of the stacked type chip package structure and the damage to the pads of the chips caused by laser drilling. Therefore, the stacked type chip package structure manufactured by the method in the disclosure has favourable reliability, lower production cost and thinner overall thickness.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 to FIG. 9 illustrate cross-sectional views of a manufacturing process of a stacked type chip package structure according to an embodiment of the invention.

FIG. 10 to FIG. 14 illustrate cross-sectional views of a part of a manufacturing process of a stacked type chip package structure according to an embodiment of the invention.

FIG. 15 to FIG. 19 illustrate cross-sectional views of a part of a manufacturing process of a stacked type chip package structure according to an embodiment of the invention.

FIG. 20 to FIG. 24 illustrate cross-sectional views of a part of a manufacturing process of a stacked type chip package structure according to an embodiment of the invention.

FIG. 25 illustrates a cross-sectional view of a stacked type chip package structure according to an embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

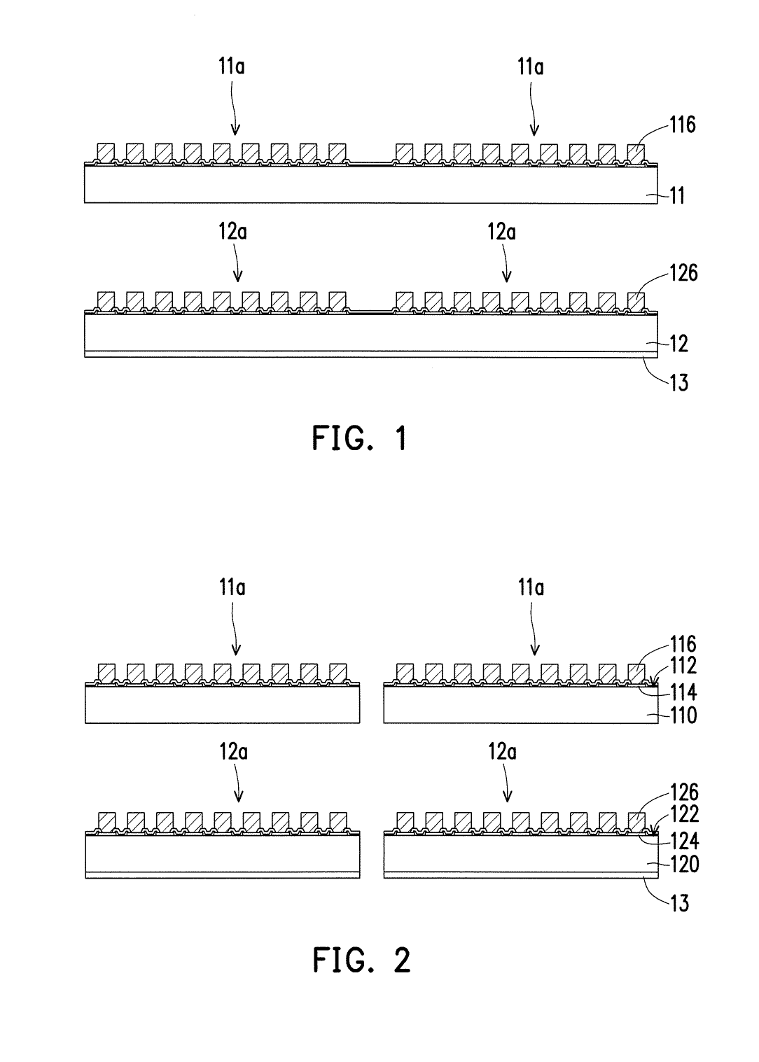

FIG. 1 to FIG. 9 illustrate cross-sectional views of a manufacturing process of a stacked type chip package structure 100 according to an embodiment of the invention. In the present embodiment, a manufacturing method of a stacked type chip package structure includes the following steps. Firstly, referring to FIG. 1, a first wafer 11 and a second wafer 12 are provided. The first wafer 11 includes a plurality of first primary chips 11a and the second wafer 12 includes a plurality of second primary chips 12a. A plurality of first terminals 116 are formed on each of the first primary chips 11a, and a plurality of second terminals 126 are formed on each of the second primary chips 12a. In the present embodiment, the first terminals 116 and the second terminals 126 are integrally formed conductive pillars as shown in FIG. 1, and the material of the first terminals 116 and the second terminals 126 may include copper. The first terminals 116 and the second terminals 126 may be copper pillars. In the present embodiment, a die attach film (DAF) 13 is attached to a back surface of the second wafer 12 as shown in FIG. 1, but the disclosure is not limited thereto.

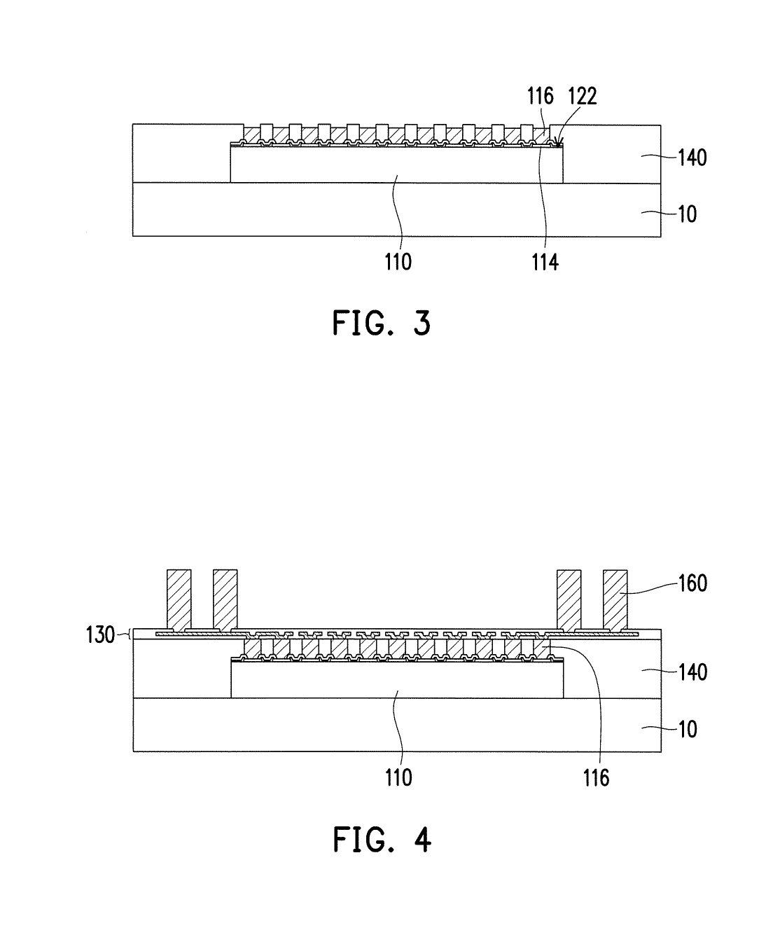

Referring to FIG. 2 and FIG. 3, the first wafer 11 is diced to separate the first primary chips 11a, and the second wafer 12 may also be diced to separate the second primary chips 12a. Then, at least one first chip 110 from the first primary chips 11a is picked and disposed on a carrier 10 as shown in FIG. 3. Referring back to FIG. 2, the first chip 110 includes a first active surface 112 and a plurality of first pads 114 located on the first active surface 112, and the first terminals 116 are disposed on the first pads 114 as shown in FIG. 3. In the present embodiment, the first chip 110 is disposed on the carrier 10 in a way that the first active surface 112 faces away from the carrier 10, but the disclosure is not limited thereto.

Then, referring to FIG. 4, a first encapsulant 140 is formed to encapsulate the first chip 110 and exposes the top surfaces of the first terminals 116. In the present embodiment, the first encapsulant 140 may firstly completely cover the first chip 110 and the first terminals 116. Then, a grinding process may be performed on the first encapsulant 140 until the top surfaces of the first terminals 116 are exposed. As such, a top surface of the first encapsulant 140 is coplanar with the top surfaces of the first terminals 116. In addition, certain treatment such as etching may be performed to further remove the top portion of the first terminals 116, so the top surfaces of the first terminals 116 is lower than a top surface of the first encapsulant 140 as shown in FIG. 3. As such, the contact area of the first terminals 116 and the first encapsulant 140 for contacting with the subsequently-formed redistribution layer (e.g. the first redistribution layer 130) is increased, so as to enhance the bonding strength between the first terminals 116, the first encapsulant 140, and the first redistribution layer 130. In some embodiments, a height difference between the top surfaces of the first terminals 116 and the top surface of the first encapsulant 140 ranges from 1 μm to 3 μm. For simplicity purpose, the top surfaces of the first terminals 116 is depicted as being substantially coplanar with the top surface of the first encapsulant 140 in the rest of the figures, but the disclosure is not limited thereto. With such configuration, the thickness of the stacked type chip package structure 100 may be further reduced, and the process of forming conductive vias for the first chip 110 by laser drilling may be omitted, so as to reduce the production cost of the stacked type chip package structure 100. Also, the damage to the first pads 114 caused by laser may be avoided since the laser drilling process is omitted herein. In addition, the integrally formed first terminals 116 may be a solid pillars while the via formed by laser process is in a taper shape with voids inside. Therefore, the first terminals 116 have better electrical performance, and the gap between any two adjacent terminals 116 is reduced.

Then, referring to FIG. 4, a first redistribution layer 130 is formed for being electrically connected to the first chip 110. In the present embodiment, the first redistribution layer 130 is formed on the first encapsulant 140, but the disclosure is not limited thereto. Then, a plurality of through pillars 160 are formed by, for example, an electroplating process.

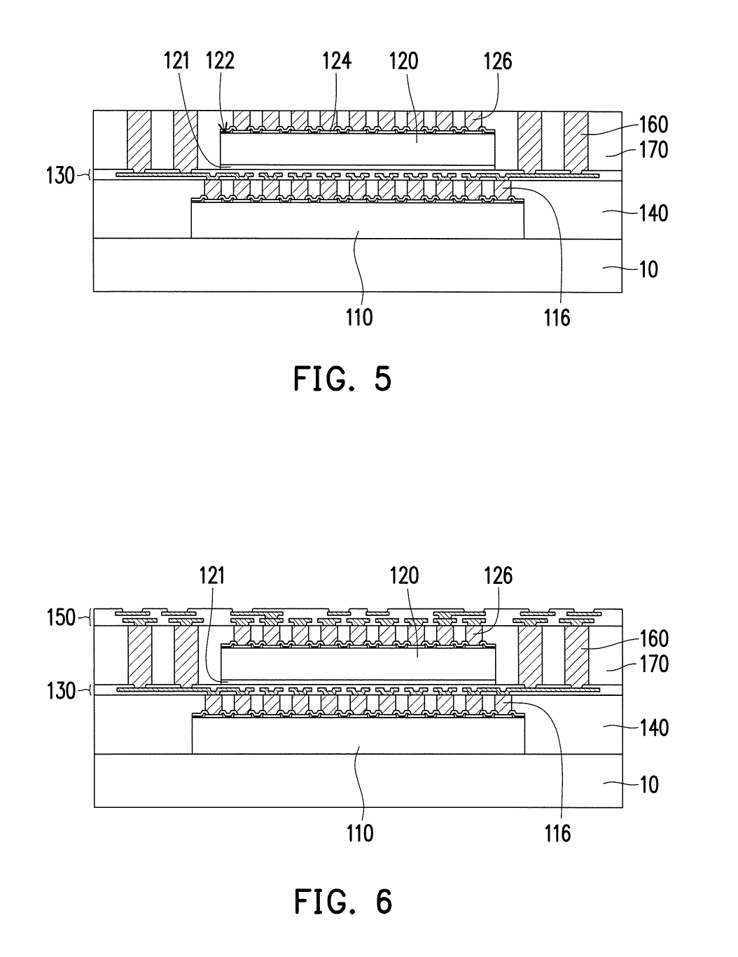

Then, referring to FIG. 5, at least one second chip 120 from the second primary chips 12a is picked and disposed on the first redistribution layer 130. In the present embodiment, the second chip 120 is disposed on the first redistribution layer 130 via a die attach film (DAF) 121. Herein, the second chip 120 includes a second active surface 122 and a plurality of second pads 124 located on the second active surface 122. The second terminals 126 are disposed on the second pads 124 as shown in FIG. 5. In the present embodiment, the second chip 120 is disposed on the first redistribution layer 130 in a way that the second active surface 122 facing away from the first redistribution layer 130, but the disclosure is not limited thereto. The through pillars 160 surround the second chip 120 and are electrically connected to the first redistribution layer 130.

Then, referring to FIG. 6, a second redistribution layer 150 is formed for being electrically connected to the second chip 120. In the present embodiment, a second encapsulant 170 may be formed to encapsulate the second chip 120 and the through pillars 160. The second encapsulant 170 exposes the top surfaces of the second terminals 126 and the top surfaces of the through pillars 160, and the second redistribution layer 150 is disposed on the second encapsulant 170 to be electrically connected to the second terminals 126 and the through pillars 160. The second redistribution layer 150 is formed to be opposite to the first redistribution layer 130. Namely, the first redistribution layer 130 and the second redistribution layer 150 are respectively located on two opposite sides of the first encapsulant 140 or the second encapsulant 170. In the present embodiment, the first redistribution layer 130 and the second redistribution layer 150 are respectively located on two opposite sides of the second encapsulant 170. Accordingly, the through pillars 160 are electrically connected to the first redistribution layer 130 and the second redistribution layer 150, and the first redistribution layer 130 is located between the first encapsulant 140 and the second encapsulant 170. In some alternative embodiments which will be discussed later, the first redistribution layer 130 and the second redistribution layer 150 are respectively located on two opposite sides of the first encapsulant 140.

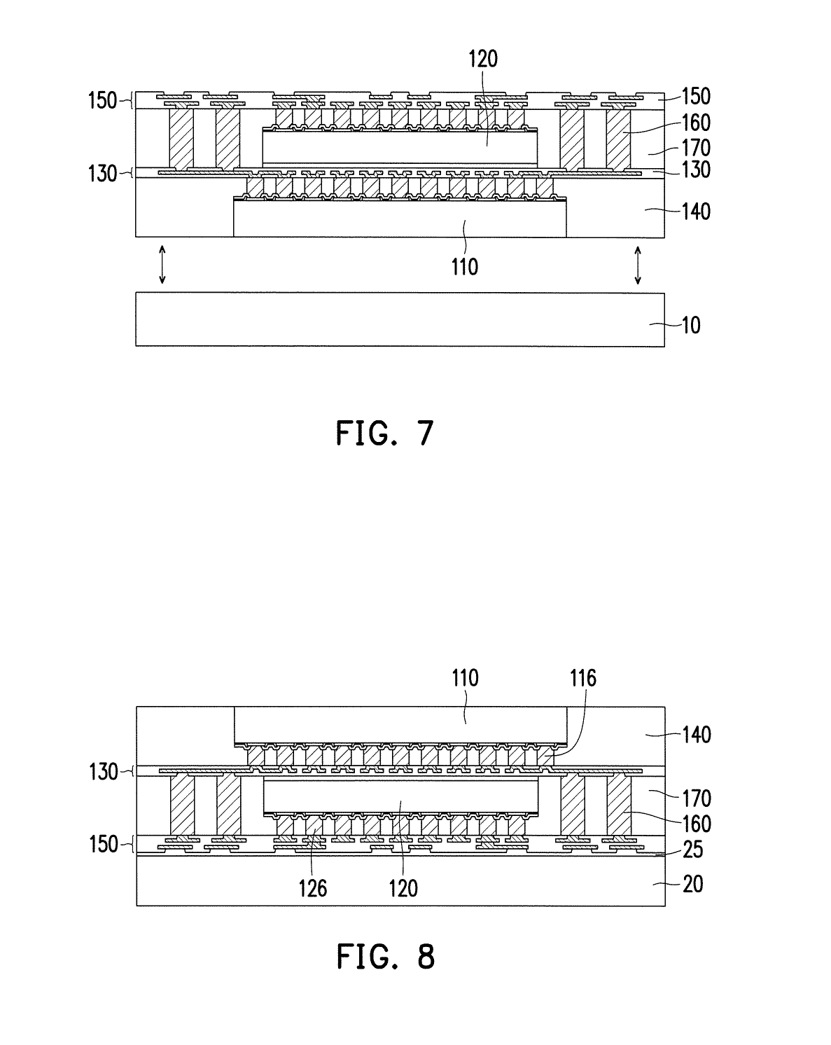

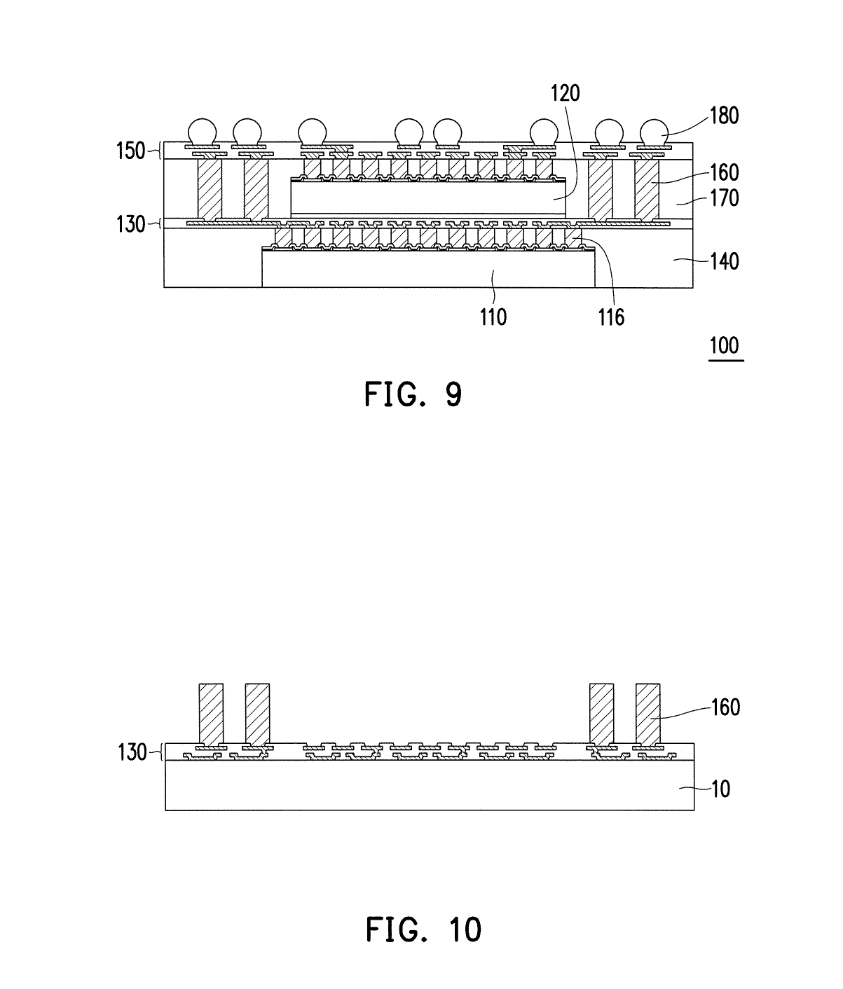

Referring to FIG. 7 and FIG. 8, the carrier 10 is removed as shown in FIG. 7. Then, the stacked type chip package structure may be flipped over and disposed on an auxiliary carrier 20 to perform a grinding process on the back surface of the first chip 110 and the first encapsulant 140. Therefore, the thickness of the stacked type chip package structure 100 is further reduced. The structure illustrated in FIG. 7 may be disposed on the auxiliary carrier 20 via, for example, a release layer 25. Then, referring to FIG. 9, the auxiliary carrier 20 is removed and a plurality of solder balls 180 are formed on the second redistribution layer 150. At the time, the manufacturing process of the stacked type chip package structure 100 may be substantially done.

FIG. 10 to FIG. 14 illustrate cross-sectional views of a part of a manufacturing process of a stacked type chip package structure 100a according to an embodiment of the invention. It is noted that the manufacturing process of the stacked type chip package structure 100a shown in FIG. 10 to FIG. 14 contains many features same as or similar to the manufacturing process of the stacked type chip package structure 100 disclosed earlier with FIG. 1 to FIG. 9. For purpose of clarity and simplicity, detail description of same or similar features may be omitted, and the same or similar reference numbers denote the same or like components. The main differences between the manufacturing process of the stacked type chip package structure 100a and 100 are described as follows.

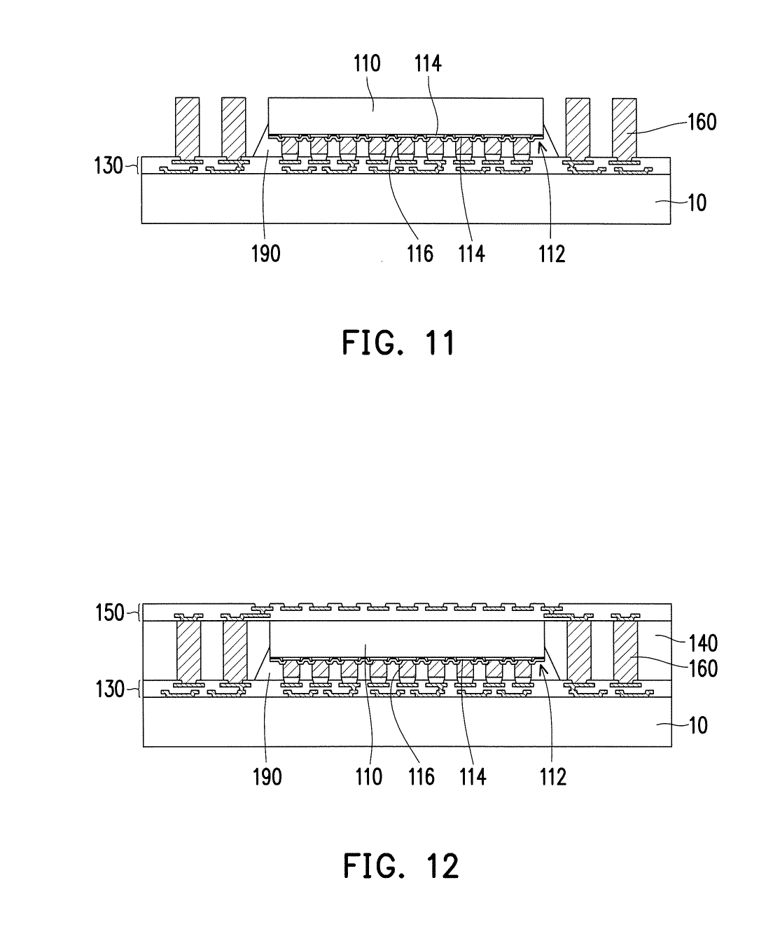

Referring to FIG. 10 and FIG. 11, in the present embodiment, the first redistribution layer 130 is formed on the carrier 10 as shown in FIG. 10, and the through pillars 160 is then formed on the first redistribution layer 130 by, for example, an electroplating process, etc. Then, at least one first chip 110 from the first primary chips (e.g. the first primary chips 11a illustrated in FIG. 2) is disposed on the first redistribution layer 130 as shown in FIG. 11. In the present embodiment, first chip 110 is disposed on the first redistribution layer 130 through the first terminals 116 by flip-chip bonding technique, so the first redistribution layer 130 is located between the first chip 110 and the carrier 10. Then, a first underfill 190 is formed between the first chip 110 and the first redistribution layer 130.

In the present embodiment, the first terminals 116 are conductive bumps which may include copper, nickel and Tin-Silver. The first terminals 116 may include a copper pillar, a Tin-Silver bump disposed on the copper pillar, and a nickel layer disposed between the copper pillar and the Tin-Silver bump, but the disclosure is not limited thereto. In the present embodiment, the first terminals 116 described above may be firstly formed on each of the first primary chips 11a of the first wafer 11 before the first wafer 11 is diced to separate the first primary chips 11a.

Referring to FIG. 12, the first encapsulant 140 is formed to encapsulate the first chip 110, the first underfill 190 and the through pillars 160. In the present embodiment, the first encapsulant 140 may firstly completely cover the first chip 110 and the through pillars 160. Then, a grinding process may be performed on the first encapsulant 140 until the top surfaces of the through pillars 160 and the back surface of the first chip 110 are exposed. As such, the thickness of the stacked type chip package structure 100a may be further reduced. Then, the second redistribution layer 150 is formed on the first encapsulant 140 to be electrically connected to the through pillars 160. The second redistribution layer 150 is formed to be opposite to the first redistribution layer 130. In the present embodiment, the first redistribution layer 130 and the second redistribution layer 150 are respectively located on two opposite sides of the first encapsulant 140.

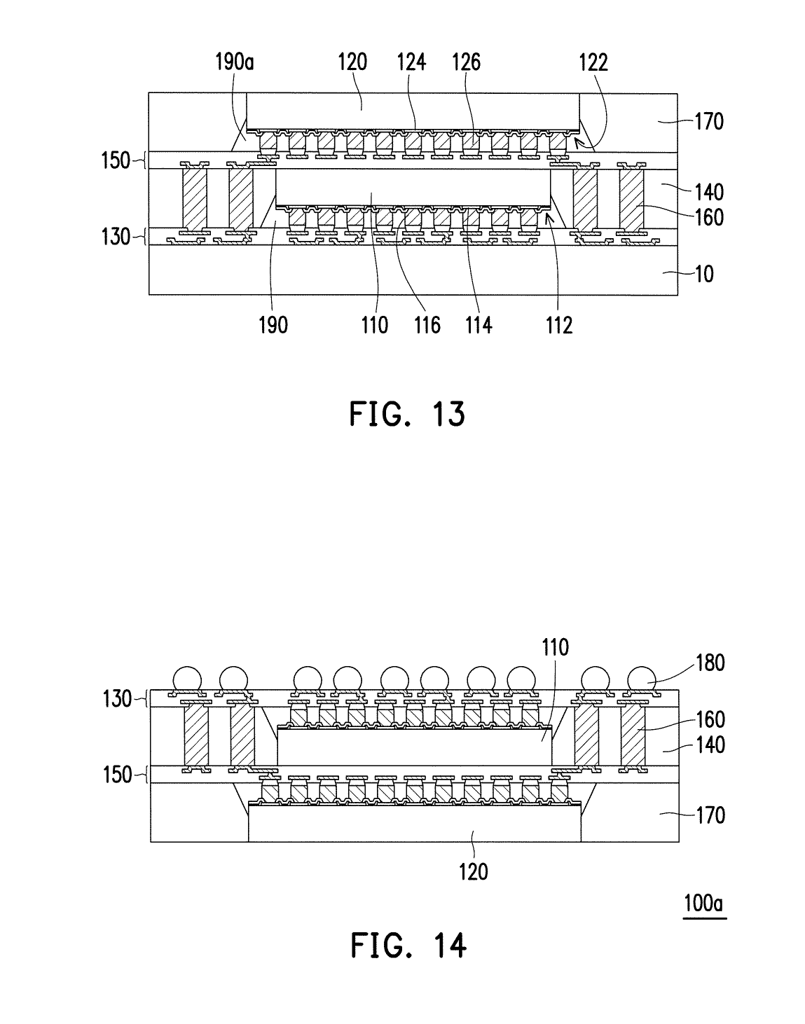

Referring to FIG. 13, at least one second chip 120 from the second primary chips (e.g. the second primary chips 12a illustrated in FIG. 2) is disposed on the second redistribution layer 150 through the second terminals 126 by flip-chip bonding technique. Then, a second underfill 190a is formed between the second chip 120 and the second redistribution layer 150. In the present embodiment, the second terminals 126 are conductive bumps which may include copper, nickel and Tin-Silver. For example, the second terminals 126 may include a copper pillar, a Tin-Silver bump disposed on the copper pillar, and a nickel layer disposed between the copper pillar and the Tin-Silver bump, but the disclosure is not limited thereto. In the present embodiment, the second terminals 126 described above may be firstly formed on each of the second primary chips 12a of the second wafer 12 before the second wafer 12 is diced to separate the second primary chips 12a. In the present embodiment, no die attach film is needed to be attached to the back surface of the second wafer 12. Then, the second encapsulant 170 is formed to encapsulate the second chip 120 and the second underfill 190a.

Then, referring to FIG. 14, the carrier 10 is removed from the first redistribution layer 130, and the solder balls 180 may be formed on the first redistribution layer 130 exposed by the carrier 10. At the time, the manufacturing process of the stacked type chip package structure 100a may be substantially done.

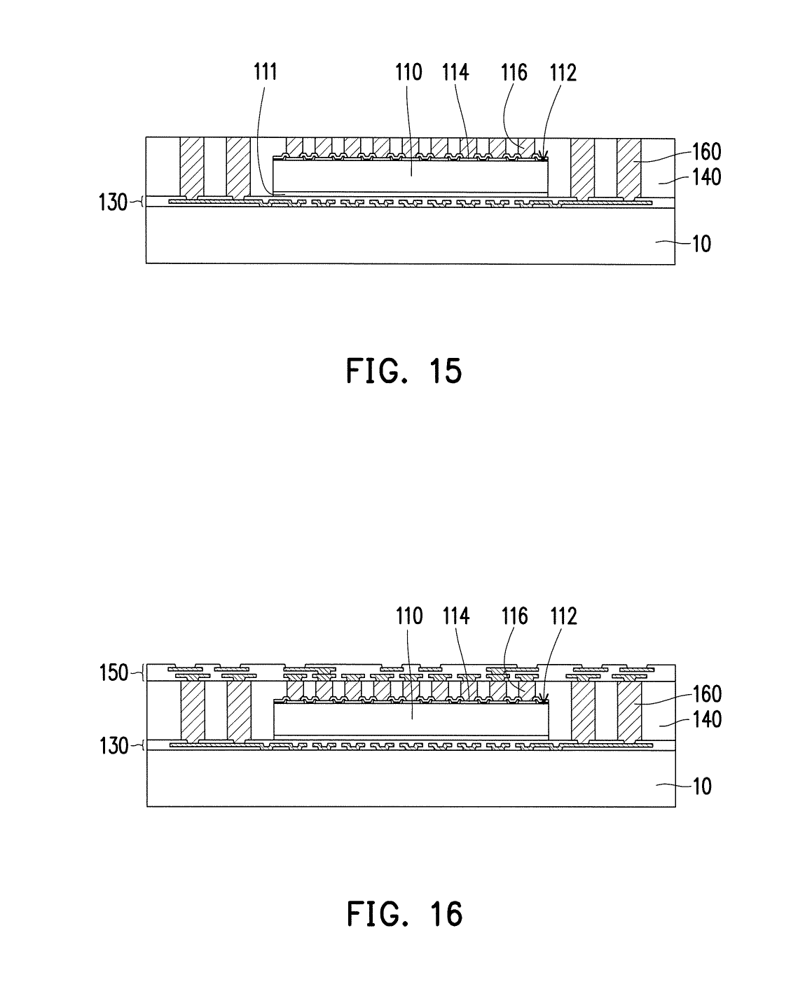

FIG. 15 to FIG. 19 illustrate cross-sectional views of a part of a manufacturing process of a stacked type chip package structure 100b according to an embodiment of the invention. It is noted that the manufacturing process of the stacked type chip package structure 100b shown in FIG. 15 to FIG. 19 contains many features same as or similar to the manufacturing process of the stacked type chip package structure 100 disclosed earlier with FIG. 1 to FIG. 9. For purpose of clarity and simplicity, detail description of same or similar features may be omitted, and the same or similar reference numbers denote the same or like components. The main differences between the manufacturing process of the stacked type chip package structure 100b and 100 are described as follows.

Referring to FIG. 15, in the present embodiment, the first redistribution layer 130 is firstly formed on the carrier 10, and then at least one first chip 110 from the first primary chips 11a is disposed on the first redistribution layer 130 via a die attach film 111. In the present embodiment, the first terminals 116 are conductive pillars, which may be integrally formed, and the first active surface 112 where the first terminals 116 are located faces away from the first redistribution layer 130. In the present embodiment, the through pillars 160 is formed on the first redistribution layer 130 and surround the first chip 110, the first encapsulant 140 encapsulates the through pillars 160 and exposes the top surfaces of the first terminals 116 and the through pillars 160.

Referring to FIG. 16, the second redistribution layer 150 is formed on the first encapsulant 140 to be electrically connected to the exposed first terminals 116 and the through pillars 160. Accordingly, the through pillars 160 are electrically connected between the first redistribution layer 130 and the second redistribution layer 150.

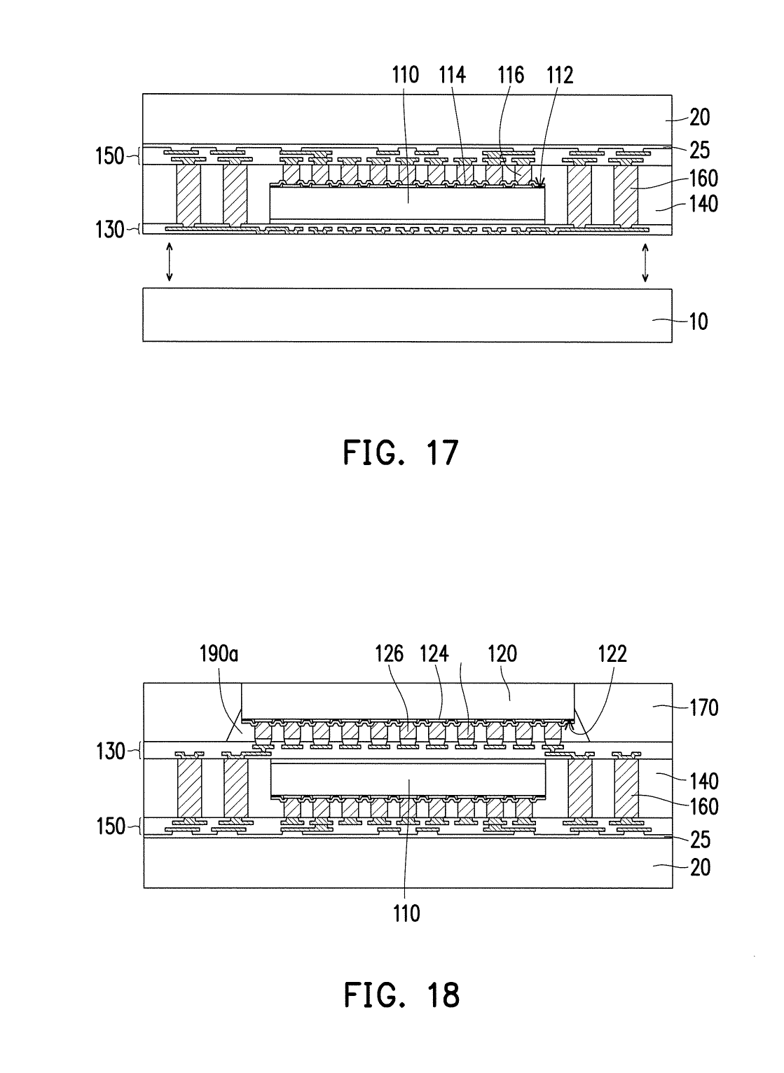

Referring to FIG. 17, an auxiliary carrier 20 is disposed on the second redistribution layer 150 via, for example, a release layer 25, and the carrier 10 is removed from the first redistribution layer 130. In addition, there may also be a release layer between the carrier 10 and the first redistribution layer 130 so the carrier 10 may be easily removed via the release layer. Then, referring to FIG. 18, the structure shown in FIG. 17 is flipped over, and at least one second chip 120 from the second primary chips 12a is disposed on the exposed first redistribution layer 130.

In the present embodiment, the second chip 120 is disposed on the first redistribution layer 130 through the second terminals 126 by flip-chip bonding technique. Then, a second underfill 190a is formed between the second chip 120 and the first redistribution layer 130. In the present embodiment, the second terminals 126 are conductive bumps which may include copper, nickel and Tin-Silver. For example, the second terminals 126 may include a copper pillar, a Tin-Silver bump disposed on the copper pillar, and a nickel layer disposed between the copper pillar and the Tin-Silver bump, but the disclosure is not limited thereto. In the present embodiment, the second terminals 126 described above may be firstly formed on each of the second primary chips 12a of the second wafer 12 before the second wafer 12 is diced to separate the second primary chips 12a. In the present embodiment, no die attach film is needed to be attached to the back surface of the second wafer 12. Then, the second encapsulant 170 is formed to encapsulate the second chip 120 and the second underfill 190a.

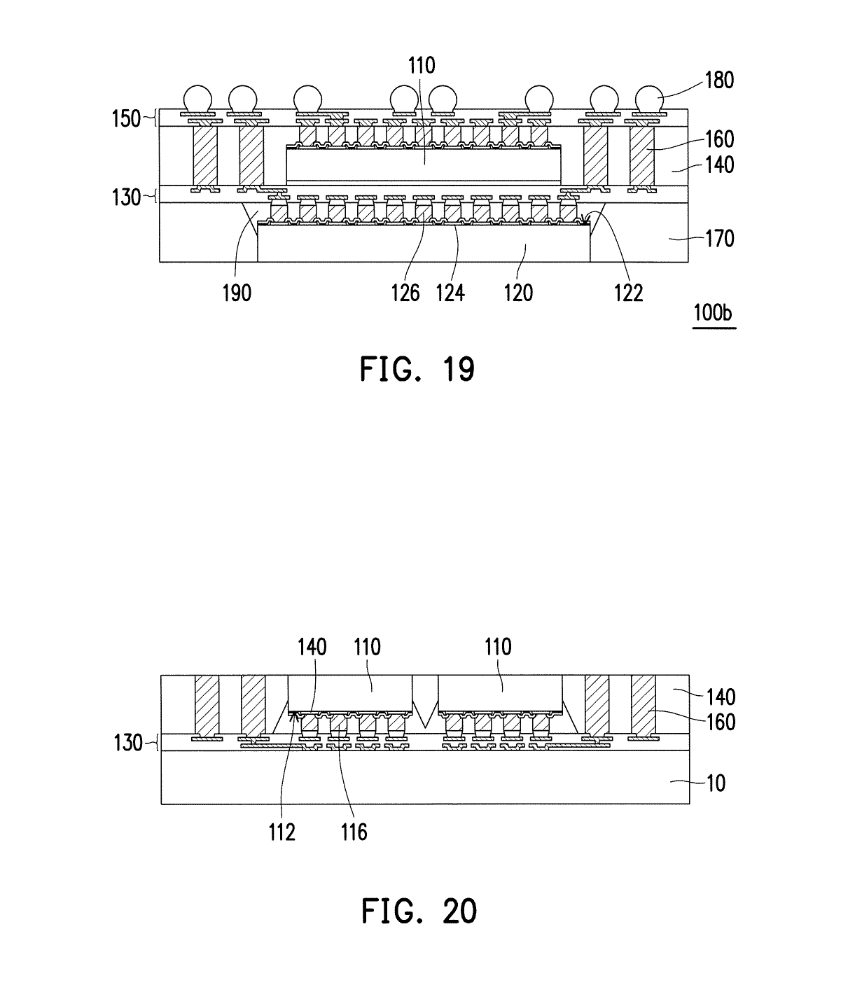

Then, the auxiliary carrier 20 is removed to expose the second redistribution layer 150 as shown in FIG. 19. Next, the solder balls 180 are disposed on the second redistribution layer 150. At the time, the manufacturing process of the stacked type chip package structure 100b may be substantially done.

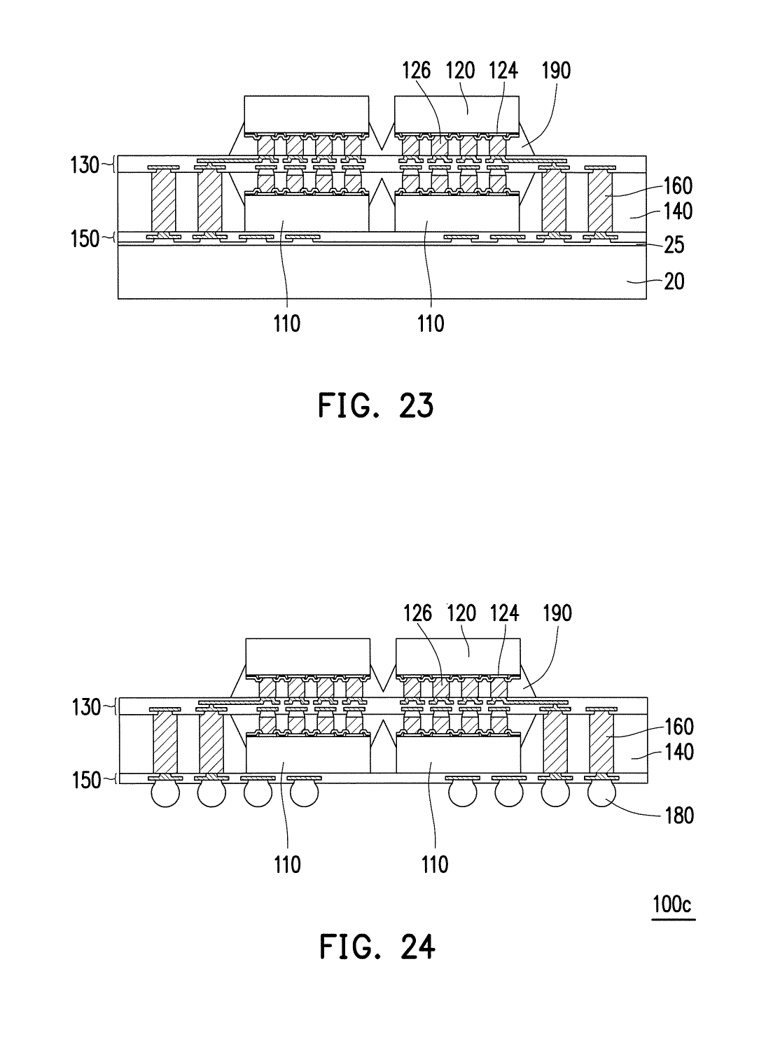

FIG. 20 to FIG. 24 illustrate cross-sectional views of a part of a manufacturing process of a stacked type chip package structure 100c according to an embodiment of the invention. It is noted that the manufacturing process of the stacked type chip package structure 100c shown in FIG. 20 to FIG. 24 contains many features same as or similar to the manufacturing process of the stacked type chip package structure 100b disclosed earlier with FIG. 15 to FIG. 19. For purpose of clarity and simplicity, detail description of same or similar features may be omitted, and the same or similar reference numbers denote the same or like components. The main differences between the manufacturing process of the stacked type chip package structure 100c and 100b are described as follows.

Referring to FIG. 20, in the present embodiment, the first redistribution layer 130 is formed on the carrier 10. Then, the through pillars 160 are formed on the first redistribution layer 130. Then, more than one of the first chips 110 (two first chips 110 are illustrated herein, but the disclosure is not limited thereto) from the first primary chips 11a are disposed on the first redistribution layer 130. It is noted that the first chips 110 disposed on the first redistribution layer 130 may be the same or may be different from each other. Namely, the first chips 110 disposed on the first redistribution layer 130 may be homogeneous or heterogeneous to each other, the disclosure is not limited the types of the first chips 110 disposed on the first redistribution layer 130. In the present embodiment, the first chips 110 are disposed on the first redistribution layer 130 through the first terminals 116 by flip-chip bonding technique, and the through pillars 160 surround the first chips 110. The first active surfaces 112 of the first chips 110 face the first redistribution layer 130, and the first terminals 116 are conductive bumps which may include copper, nickel and Tin-Silver. For example, the first terminals 116 may include a copper pillar, a Tin-Silver bump disposed on the copper pillar, and a nickel layer disposed between the copper pillar and the Tin-Silver bump, but the disclosure is not limited thereto. In the present embodiment, the first terminals 116 described above may be firstly formed on each of the first primary chips 11a of the first wafer 11 before the first wafer 11 is diced to separate the first primary chips 11a.

Next, the first encapsulant 140 is formed to encapsulate the first chips 110 and the through pillars 160. In the present embodiment, the first encapsulant 140 may firstly completely cover the first chips 110 and the through pillars 160. Then, a grinding process may be performed on the first encapsulant 140 until the back surfaces of the first chips 110 and the top surfaces of the through pillars 160 are exposed, so as to further reduce the thickness of the stacked type chip package structure 100c.

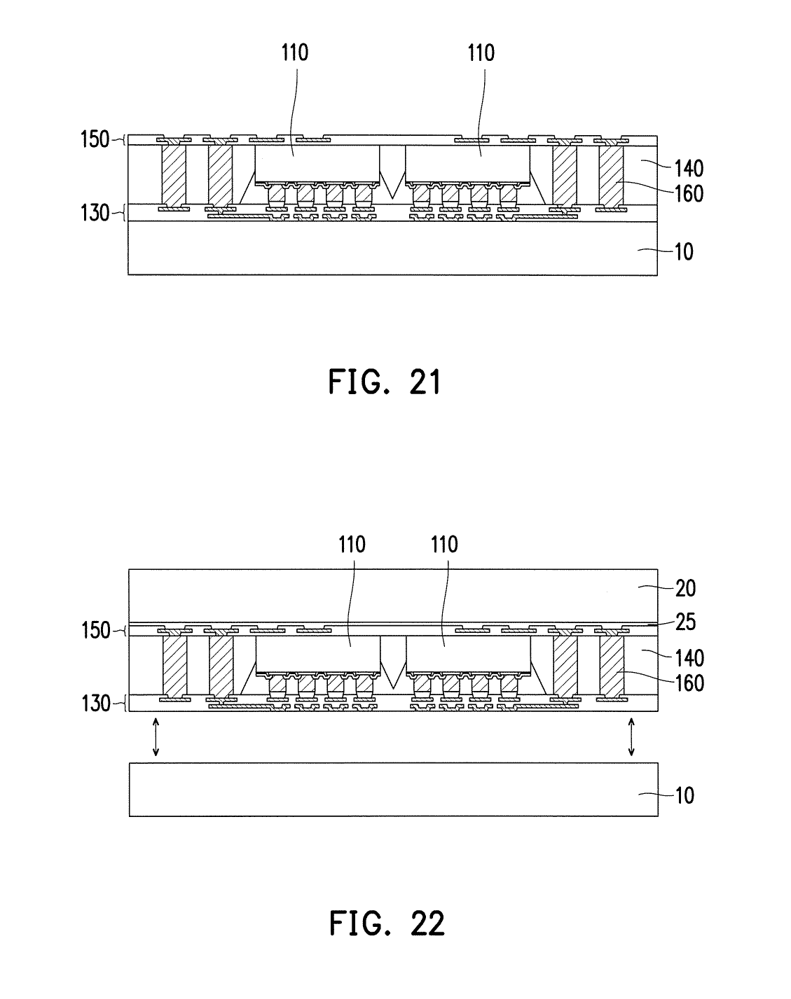

Then, referring to FIG. 21, the second redistribution layer 150 is formed on the first encapsulant 140 to be electrically connected to the through pillars 160. Accordingly, the through pillars 160 electrically connect the first redistribution layer 130 and the second redistribution layer 150. Then, the following manufacturing process (illustrated in FIG. 22 to FIG. 24) to be performed on the structure shown in FIG. 21 are substantially the same as the manufacturing process illustrated in FIG. 13 and FIG. 14, so detail description of same or similar features are omitted herein.

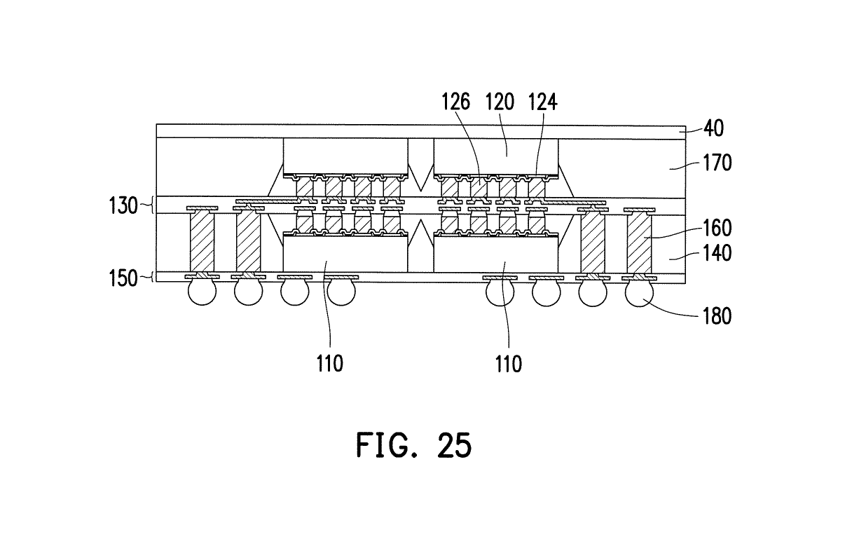

In the present embodiment, the process of forming underfill 190 may be omitted. Also, the second encapsulant 170 may or may not be formed to encapsulate the second chips 120 (two second chips 120 are illustrated herein, but the disclosure does not limit the number of the second chips 120). Similarly, the second encapsulant 170 in the package structures 100a and 100b as shown in FIGS. 14 and 19 may also not be formed to encapsulate the second chips 120. In the embodiment of the stacked type chip package structure 100c having the second encapsulant 170, the second encapsulant 170 may or may not expose the back surfaces of the second chips 120. Similarly, the second encapsulant 170 in the package structures 100a and 100b as shown in FIGS. 14 and 19 may also not expose the back surfaces of the second chips 120. In addition, in the embodiment of the second encapsulant 170 exposing the back surfaces of the second chips 120 as shown in FIG. 25, a heat sink 40 may be disposed on the second encapsulant 170 and in contact with the back surfaces of the second chips 120. Similarly, the heat sink 40 may also be disposed on the second encapsulant 170 in the package structures 100a and 100b as shown in FIGS. 14 and 19 and in contact with the back surfaces of the second chips 120.

In sum, in the present disclosure, the first terminals are formed on the first chip and then the first chip is disposed on the carrier. Then, the first encapsulant is formed to encapsulate the first chip, and the first redistribution layer is formed on the encapsulant to electrically connect the first chip. Then, the second chip with second terminals formed thereon may be sequentially stacked on the first redistribution layer and the second redistribution layer is formed to be electrically connected to the second chip, and the through pillars is formed to electrically connect the first and second redistribution layers.

With such configuration, the thickness of the stacked type chip package structure is further reduced, and the process of forming conductive vias for the chips by laser drilling is omitted, so as to reduce the production cost of the stacked type chip package structure. Also, the damage to the pads of the chips caused by laser is avoided since the laser drilling process is omitted herein. In addition, the terminals of the disclosure are solid pillars pre-formed on the chips, while the via formed by laser process is in a taper shape with voids inside. Therefore, the terminals of the disclosure have better electrical performance, and the gap between any two adjacent terminals is reduced. Therefore, the stacked type chip package structure manufactured by the method provided in the disclosure has favourable reliability, lower production cost and thinner overall thickness.

It will be apparent to those skilled in the art that various modifications and variations may be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A manufacturing method of a stacked type chip package structure, comprising:
disposing at least one first chip over a carrier, wherein the at least one first chip comprises a first active surface and a plurality of first pads located on the first active surface, and a plurality of first terminals are disposed on the first pads;
forming a first redistribution layer electrically connected to the first chip;
forming a first encapsulant to encapsulate the at least one first chip and exposes a top surface of each of the first terminals;
disposing at least one second chip over the first encapsulant and the at least one first chip, wherein the at least one second chip comprises a second active surface and a plurality of second pads located on the second active surface, and a plurality of second terminals are disposed on the second pads;
forming a second encapsulant to encapsulate the at least one second chip and expose a top surface of each of the second terminals of the at least one second chip; and
forming a second redistribution layer opposite to the first redistribution layer, wherein the first redistribution layer and the second redistribution layer are respectively located on two opposite sides of the first encapsulant or the second encapsulant; and
forming a plurality of through pillars, wherein the through pillars electrically connects the first redistribution layer and the second redistribution layer.

2. The manufacturing method of the stacked type chip package structure as claimed in claim 1, wherein the step of disposing the at least one first chip on the carrier and the step of forming the first encapsulant to encapsulate the at least one first chip precede the step of forming the first redistribution layer, and the step of forming the first redistribution layer precedes the step of forming the through pillars.

3. The manufacturing method of the stacked type chip package structure as claimed in claim 1, wherein the step of forming the first redistribution layer precedes the step of disposing the at least one first chip on the carrier and the step of forming the through pillars, and the step of disposing the at least one first chip on the carrier and the step of forming the through pillars precede the step of forming the first encapsulant to encapsulate the at least one first chip.

4. The manufacturing method of the stacked type chip package structure as claimed in claim 3, wherein the at least one first chip is disposed such that the first active surface faces the carrier, and the first pads located on the first active surface of the at least one first chip are electrically connected to the first redistribution layer through the first terminals.

5. The manufacturing method of the stacked type chip package structure as claimed in claim 4, wherein the at least one second chip is disposed such that the second pads located on the second active surface of the at least one second chip are electrically connected to the second redistribution layer through the second terminals.

6. The manufacturing method of the stacked type chip package structure as claimed in claim 4, wherein the at least one second chip is disposed such that the second pads located on the second active surface of the at least one second chip are electrically connected to the first redistribution layer through the second terminals.

7. The manufacturing method of the stacked type chip package structure as claimed in claim 3, wherein the at least one first chip is disposed such that the first active surface faces away from the carrier, and the first pads located on the first active surface of the at least one first chip are electrically connected to the second redistribution layer through the first terminals.

8. A stacked type chip package structure, comprising:
a first chip, wherein each of the first chips comprises a first active surface and a plurality of first pads located on the first active surface;
a plurality of first terminals disposed on the first pads;
a first redistribution layer electrically connected to the first chip;
a first encapsulant encapsulating the first chip and exposing top surfaces of the first terminals;
a second chip disposed over the first encapsulant, wherein the second chip comprises a second active surface and a plurality of second pads located on the second active surface;
a plurality of second terminals disposed on the second pads;
a second redistribution layer electrically connected to the second chip; and
a plurality of through pillars electrically connecting the first redistribution layer and the second redistribution layer.

9. The stacked type chip package structure as claimed in claim 8, wherein the first terminals are conductive pillars, which are integrally formed, the first active surface faces away from the carrier, the first redistribution layer is disposed on the first encapsulant, the second chip is disposed on the first redistribution layer with the second active surface faces away from the first redistribution layer, and the through pillars are disposed on the first redistribution layer and surround the second chip.

10. The stacked type chip package structure as claimed in claim 9, further comprising:
a second encapsulant encapsulating the second chip and the through pillars, wherein the second encapsulant exposes top surfaces of the second terminals and top surfaces of the through pillars, and the second redistribution layer is disposed on the second encapsulant; and
a plurality of solder balls disposed on the second redistribution layer.

11. The stacked type chip package structure as claimed in claim 8, wherein the first chip is disposed on the first redistribution layer through the first terminals, and the first terminals are conductive bumps, which comprises copper, nickel and Tin-Silver, the through pillars are disposed on the first redistribution layer, the first encapsulant encapsulates the through pillars and exposes top surfaces of the through pillars, and the second redistribution layer is disposed on the first encapsulant.

12. The stacked type chip package structure as claimed in claim 11, further comprising:
a first underfill disposed between the first chip and the first redistribution layer, wherein the first encapsulant encapsulates the first chip and the first underfill.

13. The stacked type chip package structure as claimed in claim 11, wherein the second chip is disposed on the second redistribution layer through the second terminals, and the second terminals are conductive bumps, which comprises copper, nickel and Tin-Silver.

14. The stacked type chip package structure as claimed in claim 13, further comprising:
a second underfill disposed between the second chip and the second redistribution layer, wherein the second encapsulant encapsulates the second chip and the second underfill.

15. The stacked type chip package structure as claimed in claim 8, wherein the first chip is disposed on the first redistribution layer.

16. The stacked type chip package structure as claimed in claim 15, wherein the first terminals are conductive pillars, which are integrally formed, and the first active surface faces away from the first redistribution layer.

17. The stacked type chip package structure as claimed in claim 15, wherein the first chip is disposed on the first redistribution layer through the first terminals, and the first terminals are conductive bumps, which comprises copper, nickel and Tin-Silver.

18. The stacked type chip package structure as claimed in claim 15, wherein the through pillars are disposed on the first redistribution layer and surround the first chip, and the first encapsulant encapsulates the through pillars and exposes top surfaces of the through pillars.

19. The stacked type chip package structure as claimed in claim 18, wherein the second redistribution layer is disposed on the first encapsulant, the second chip is disposed on the first redistribution layer through the second terminals, and the second terminals are conductive bumps, which comprises copper, nickel and Tin-Silver.

20. The stacked type chip package structure as claimed in claim 19, further comprising:
an underfill disposed between the second chip and the first redistribution layer;
a second encapsulant encapsulating the second chip and the underfill; and
a plurality of solder balls disposed on the second redistribution layer.
